(19) United States
(12) Patent Application Publication
(10) Pub. No.: US 2023/0287566 A1
(43) Pub. Date: Sep. 14, 2023

(54) METHOD AND APPARATUS FOR PRODUCING A GAS CURTAIN OF PURGE GAS IN A SLIT VALVE TUNNEL

(71) Applicant: SILTRONIC AG, Munich (DE)

(72) Inventors: Patrick MOOS, Pleiskirchen (DE); Marco FELDMANN, Oberschoena (DE)

(73) Assignee: SILTRONIC AG, Munich (DE)

(21) Appl. No.: 18/014,386

(22) PCT Filed: Jun. 18, 2021
(86) PCT No.: PCT/EP2021/066637

§ 371 Date: Jan. 4, 2023

(30) Foreign Application Priority Data
Jul. 6, 2020 (EP) 20184139.2

(51) Int. Cl. C23C 16/455; C23C 16/44; F16K 3/02; F16K 51/02; H01J 37/32; H01L 21/67; H01L 21/677

(52) U.S. Cl. CPC C23C 16/45519; C23C 16/4408; F16K 3/0245; F16K 51/02; H01J 37/32449; H01L 21/67126; H01L 21/67201; H01L 21/67703; H01L 21/67748

(57) ABSTRACT

Contamination of semiconductor wafers during coating and other operations is mitigated by passing the wafer through a tunnel with a slit providing a gas curtain which impinges upon the wafer as the wafer is transported from one station to the next station in the processing apparatus.

### CROSS REFERENCE TO RELATED APPLICATIONS

This application is the U.S. National Phase of PCT Application No. PCT/EP2021/066637 filed Jun. 18, 2021, which claims priority to European Application No. 20184139.2 filed Jul. 6, 2020, the disclosure of which are incorporated in their entirety by reference herein.

### BACKGROUND OF THE INVENTION

### 1. Field of Invention

The invention provides a method for producing a gas curtain of purge gas in a slit valve tunnel of an apparatus for treating a semiconductor wafer, for example an apparatus for heat treating the semiconductor wafer or for depositing a layer on an upper side of the semiconductor wafer. The invention also provides a slit valve tunnel for such an apparatus.

### 2. Description of the Related Art

In US20100190343A1 there is disclosed an apparatus for treating a semiconductor wafer which comprises typical modules, in particular a process chamber, a transfer chamber and a load lock. The semiconductor wafer to be treated is transported into the modules in a predefined order. The modules are separated by ports.

In KR101875305B1 it is proposed to use a slit valve tunnel as the port and to direct a purge gas over the semiconductor wafer while the semiconductor wafer is being transported through the slit valve tunnel, in order to protect the semiconductor wafer from contamination by particles.

In US20150083330A1 there is described a slit valve tunnel in which the purge gas is directed through holes from top to bottom to the semiconductor wafer being transported through the tunnel.

There is a further need for improvement because particles can accumulate in the slit valve tunnel and the slit valve tunnel can itself become a particle source over time.

### SUMMARY OF THE INVENTION

The object of the present invention is to largely eliminate the risk of semiconductor wafers being contaminated by particles as they are being transported through a slit valve tunnel.

The object of the invention is achieved by a method for producing a gas curtain of purge gas in a slit valve tunnel of an apparatus for treating a semiconductor wafer. The purge gas is directed to two ends of a channel which is arranged in a top portion of the slit valve tunnel and covered with a removable cover. The purge gas is directed in the form of a gas curtain through a slit in the bottom of the channel to a bottom portion of the slit valve tunnel while a semiconductor wafer is being transported through a through-opening between the top portion and the bottom portion of the slit valve tunnel.

In the direction of movement from the top portion to the bottom portion, the gas curtain preferably impinges on the surface of the semiconductor wafer at a right angle.

According to another preferred embodiment of the invention, the slit in the bottom of the channel is laterally delimited by a wall which is beveled, whereby the gas curtain directed to the bottom portion of the slit valve tunnel is diverted so that it impinges on the surface of the semiconductor wafer at an angle not equal to 90°. Preferably, particles lying on the semiconductor wafer are subjected, owing to the gas curtain impinging obliquely on the surface of the semiconductor wafer, to a movement impetus which is directed counter to the direction of movement of the semiconductor wafer, if the semiconductor wafer is transported from a transfer chamber to a process chamber or to a lock chamber. In this way, particles are cleaned from the surface of the semiconductor wafer and particles in the slit valve tunnel are moved away from the process chamber.

The invention additionally provides a slit valve tunnel of an apparatus for treating a semiconductor wafer, comprising a top portion, a bottom portion and a through-opening between the top portion and the bottom portion for the transport of the semiconductor wafer through the slit valve tunnel along a transport path, comprising
a recess on an upper side of the top portion;
a removable cover for covering the recess;
a channel in the recess, the channel extending transversely to the transport path;
a slit in the bottom of the channel for the passage of purge gas;
holes in the top portion for feeding the purge gas to two ends of the channel, whereby, on feeding of the gas, there is formed a gas curtain which is oriented from the top portion to the bottom portion of the slit valve tunnel.

By directing the purge gas to both ends of the channel and through the slit in the channel to the semiconductor wafer, a homogeneous gas curtain is formed, so that particles can be removed with the same effectiveness regardless of their position on the semiconductor wafer. Because the channel is accessible through a removable cover, the critical region, in which particles can accumulate and which can become a source of contamination of semiconductor wafers by particles, is readily accessible for cleaning measures.

The gas curtain extends over a distance which is greater than the diameter of a semiconductor wafer transported through the through-opening of the slit valve tunnel. According to one embodiment, the length of the distance, and thus the length of the channel, is more than 300 mm, particularly preferably 320 mm. According to one embodiment, the width of the slit in the bottom of the channel is adjusted in order to achieve a desired flow speed of the gas curtain.

According to a preferred embodiment, the slit in the bottom of the channel has vertical walls laterally delimiting said slit, so that the gas curtain impinges the surface of the semiconductor wafer at an angle of 90°.

According to another preferred embodiment, the slit in the bottom of the channel has a wall laterally delimiting said slit and arranged in an oblique manner. The gas curtain is diverted by the wall so that it impinges the surface of the semiconductor wafer at an angle not equal to 90°.

The cover is preferably removed at predetermined intervals, for example in the course of maintenance of the apparatus for treating the semiconductor wafer, and the cover, the recess that receives it and the channel are then cleaned and dried. Cleaning and drying can be carried out comparatively quickly and without any special effort.

The cover fills the recess and is removably fastened to the upper side of the top portion of the slit valve tunnel. According to one embodiment, the fastening means are screws, preferably screws of plastic materials or ceramics. According to one embodiment, a seal is present, which prevents the passage of purge gas between the cover and the recess.

The slit valve tunnel has a front side and a rear side. According to one embodiment, the front side is the side that is adjacent to a transfer chamber and the rear side is the side that is adjacent to a process chamber or a lock chamber.

In the top portion of the slit valve tunnel there are arranged two holes for feeding purge gas to the two ends of the channel. According to one embodiment, the holes are situated on the rear side of the slit valve tunnel in the region of two rounded upper corners of the rear side.

The slit valve tunnel is able to be closed by a door. According to one embodiment, the door closes the through-opening on the front side of the slit valve tunnel.

The slit valve tunnel is part of an apparatus for treating a semiconductor wafer. According to one embodiment, the apparatus is an apparatus for depositing an epitaxial layer on a substrate wafer, preferably an apparatus for depositing an epitaxial layer of silicon on a substrate wafer of single-crystal silicon. According to another embodiment, it is an apparatus for heat treating a semiconductor wafer, preferably a semiconductor wafer of single-crystal silicon.

The invention will be described further hereinbelow with reference to drawings.

### BRIEF DESCRIPTION OF THE DRAWINGS

FIG. 1 shows an embodiment of a slit valve tunnel in a perspective view.

FIG. 2 shows the slit valve tunnel according to FIG. 1 with the cover removed.

FIG. 3 is a view of the rear side of the slit valve tunnel according to FIG. 1 with an active gas curtain.

FIG. 4 is a cross-sectional schematic diagram of the slit valve tunnel according to FIG. 1 from the side.

FIG. 5 is a diagram of a cross-section of the slit valve tunnel according to FIG. 1 in a first embodiment.

FIG. 6 is a diagram of a cross-section of the slit valve tunnel according to FIG. 1 in a second embodiment.

### LIST OF REFERENCE NUMERALS USED

1 slit valve tunnel
2 top portion
3 bottom portion
4 through-opening
5 rear side
6 cover
7 holes
8 recess
9 channel
10 ends
11 gas curtain
12 transport path
13 wall
A first module
B second module

### DETAILED DESCRIPTION OF THE PREFERRED EMBODIMENTS

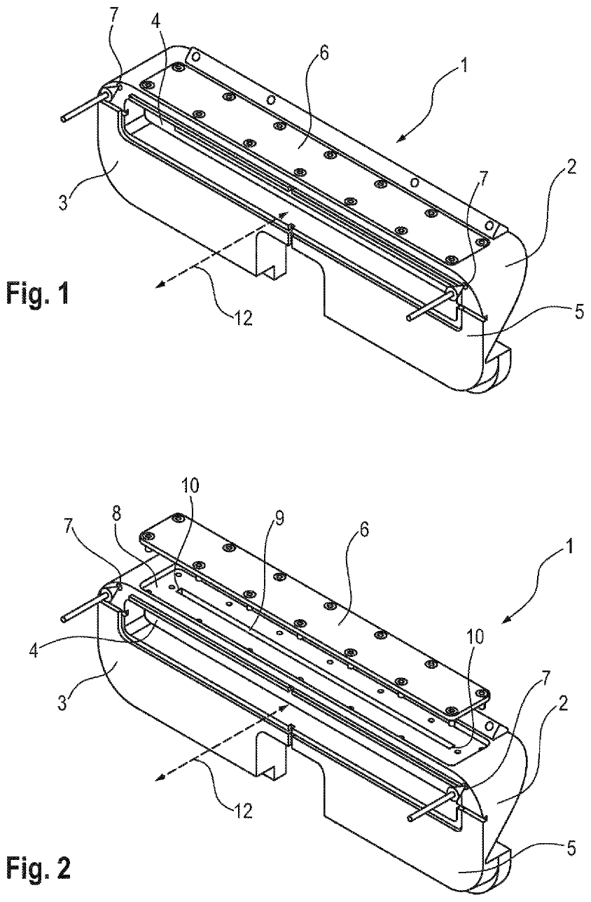

FIG. 1 shows a preferred embodiment of the slit valve tunnel 1 in a perspective view. The slit valve tunnel 1 comprises a top portion 2, a bottom portion 3 and a through-opening 4 between the top portion and the bottom portion. In this view, the rear side 5 of the slit valve tunnel 1 can be seen. A removable cover 6 is fastened to the upper side of the top portion by means of screws. In the region of two rounded upper corners of the rear side 5 of the slit valve tunnel 1 there are provided two holes 7 through which purge gas is directed to the two ends of a channel which is covered by the cover 6. Arrows symbolize the direction of flow of the purge gas.

FIG. 2 shows the slit valve tunnel 1 according to FIG. 1 with the cover 6 removed. On the upper side of the top portion 2 there is provided a recess 8 into which the cover 6 fits positively. A channel 9 having two ends 10 is incorporated in the recess, which channel extends almost over the width of the through-opening 4 and is open at the bottom to a slit (not shown).

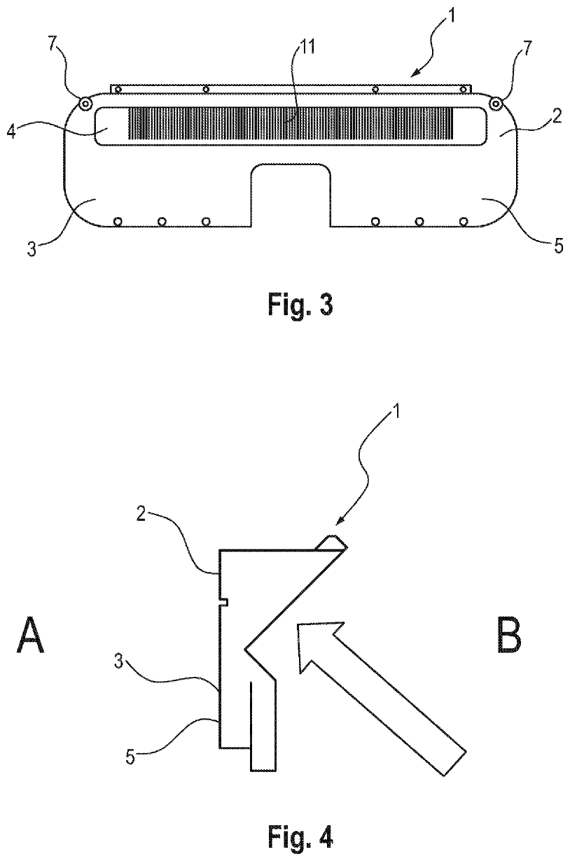

FIG. 3 is a view of the rear side 3 of the slit valve tunnel according to FIG. 1 with an active gas curtain 11 of purge gas.

FIG. 4 is a schematic diagram of the slit valve tunnel according to FIG. 1 from the side, wherein the rear side 5 of the slit valve tunnel 1 is adjacent to a module A of the apparatus for treating a semiconductor wafer and the front side of the slit valve tunnel 1 is adjacent to a module B of the apparatus. The arrow symbolizes the direction of movement of a door (not shown) for closing the through-opening 4. The module A is, for example, a process chamber or a lock chamber and module B is a transfer chamber.

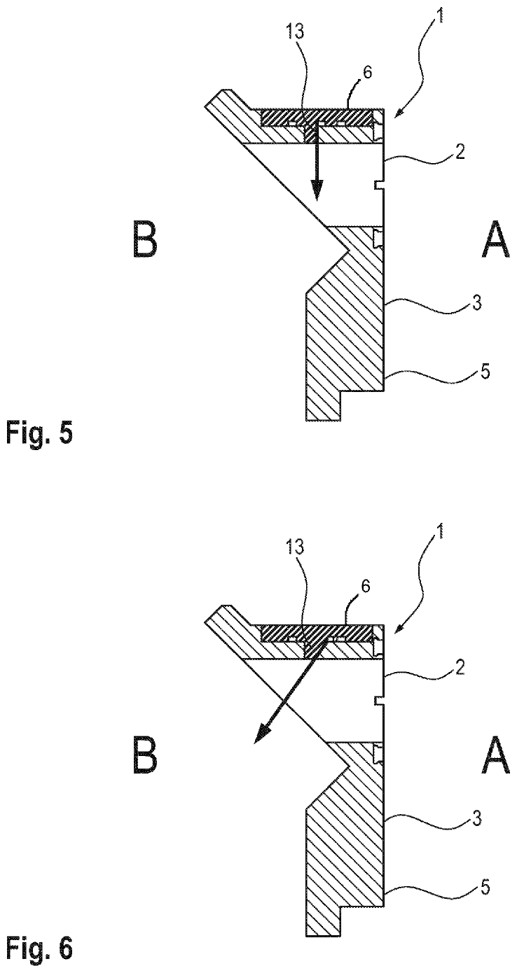

FIG. 5 is a diagram of a section of the slit valve tunnel in a preferred embodiment, in which the slit in the bottom of the channel is delimited by a vertical wall 13. The gas curtain impinges on the wafer at an angle of 90°.

FIG. 6 is a diagram of a section of the slit valve tunnel in another preferred embodiment, in which the slit in the bottom of the channel is delimited by a wall 13 which is beveled. Owing to the wall, the gas curtain is diverted into the direction in which the arrow points.

The above description of exemplary embodiments is to be understood as being by way of example. The disclosure made thereby on the one hand makes it possible for the skilled person to understand the present invention and the advantages associated therewith and on the other hand also includes variations and modifications of the described structures and method that are obvious in the understanding of the skilled person. All such variations and modifications as well as equivalents are therefore to be covered by the scope of protection of the claims.

1.-7. (canceled)

8. An apparatus for treating a semiconductor wafer comprising:
a tunnel having a first portion and a second portion opposite the first portion, the tunnel having an opening defining a transport path for transporting a semiconductor wafer from a first side to a second side of the tunnel or vice versa, the opening being between the first portion and a second portion and in communication with a channel via a slit, the channel extending from a first end to a second end of the first portion and the slit being laterally defined by a wall; and
a cover configured to be removably fastened to the tunnel along the channel;
wherein, during operation, a gas is directed through the channel forming a gas curtain from the first portion towards the second portion such that it impinges a surface of the semiconductor wafer that is transported along the transport path from the first side through the opening to the second side.

9. The apparatus of claim 8, wherein the channel is configured to receive the gas from the first and second ends.

10. The apparatus of claim 9, wherein the tunnel defines a first hole configured to feed the gas to the first end of the channel and a second hole configured to feed the gas to the second end of the channel.

11. The apparatus of claim 10, wherein the first and second holes are defined in the first side.

12. The apparatus of claim 8, wherein the tunnel includes a recess on an exterior of the first portion for receiving the cover.

13. The apparatus of claim 12, wherein the channel is disposed in the recess.

14. The apparatus of claim 8, wherein the wall is perpendicular to the transport path.

15. The apparatus of claim 8, wherein at least a portion of the wall is beveled.

16. The apparatus of claim 8, wherein the channel extends transversely to the transport path.

17. The apparatus of claim 8, further comprising a first module adjacent the first side of the tunnel, and a second module adjacent the second side of the tunnel such that when the semiconductor wafer is transported through the opening it travels from the first module to the second module.

18. The apparatus of claim 17, wherein the first module is a process chamber, or a lock camber and the second module is transfer chamber.

19. The apparatus of claim 18, wherein the wall is beveled opposite the process chamber or lock chamber such that the gas curtain directs particles away from the process chamber or lock chamber.

20. The apparatus of claim 8, further comprising a door to close the opening.

21. The apparatus of claim 8, wherein the first portion is a top portion, and the second portion is a bottom portion such that when gas is directed through the channel to form the gas curtain the gas curtain travels from the top portion towards the bottom portion.

22. A method for protecting a semiconductor wafer from contamination comprising:
directing a purge gas through the channel of the apparatus of claim 8 to form the gas curtain; and
transporting the semiconductor wafer along transport path such that the gas curtain impinges the surface of the semiconductor wafer.

23. The method of claim 22, wherein the cover is removed before or after the gas curtain is formed and the tunnel is cleaned along the channel.

24. The method of claim 22, wherein the gas curtain impinges the surface of the semiconductor wafer at an angle of 90°.

25. The method of claim 22, wherein the gas curtain impinges the surface of the semiconductor wafer at an angle not equal to 90°.

26. The method of claim 25, wherein the gas curtain is directed counter to a direction the semiconductor wafer is being transported along.

27. The method of claim 22, wherein the semiconductor wafer is transported from a transfer chamber adjacent the tunnel to a process chamber or a lock chamber adjacent the tunnel.

28. The method of claim 27, wherein the gas curtain is directed in a direction away from the process chamber or the lock chamber.
